(19) United States
(12) Patent Application Publication
(10) Pub. No.: US 2015/0056472 A1
(43) Pub. Date: Feb. 26, 2015

(54) Laminate for Printed Circuit Board and Printed Circuit Board Using The Same

(71) Applicant: SAMSUNG ELECTRO-MECHANICS CO., LTD., Suwon-Si (KR)

(72) Inventors: Chung Hee LEE, Suwon-Si (KR); Jae Choon Cho, Suwon-Si (KR); Hee Sun Chun, Suwon-Si (KR); Yong Yoon Jang, Suwon-Si (KR); Dong Hoon Kim, Suwon-Si (KR); Choon Keun Lee, Suwon-Si (KR)

(73) Assignee: SAMSUNG ELECTRO-MECHANICS CO., LTD., Suwon-Si (KR)

(21) Appl. No.: 14/465,818

(22) Filed: Aug. 21, 2014

(30) Foreign Application Priority Data
Aug. 23, 2013 (KR) 10-2013-0100627

(51) Int. Cl. H05K 1/03; H05K 1/02; H05K 1/11

(52) U.S. Cl. CPC H05K 1/0366; H05K 1/036; H05K 1/115; H05K 1/0298; H05K 2201/0137
USPC 428/704; 174/262

(57) ABSTRACT

Disclosed herein are a laminate for a printed circuit board, a printed circuit board using the same, and a method of manufacturing the same.

The laminate for a printed circuit board includes: a first insulating film; and a second insulating film formed on the first insulating film, wherein a content of a reaction accelerator in the first insulating film is different from that of the second insulating film.

### CROSS REFERENCE TO RELATED APPLICATION

This application claims the benefit of Korean Patent Application No. 10-2013-0100627 filed on Aug. 23, 2013, entitled “Laminate for Printed Circuit Board and Printed Circuit Board Using the Same” which is hereby incorporated by reference in its entirety into this application.

### BACKGROUND OF TEE INVENTION

1. Technical Field

The present invention relates to a laminate for a printed circuit board and a printed circuit board using the same.

2. Description of the Related Art

As current IT devices become converged and small-sized, the thickness of printed circuit boards (PCBs) becomes thinner than before so as to form high density circuits.

However, in manufacturing PCBs, defects may arise even with a small scratch, such that the yield rate is lowered. As a result of research about factors causing defects in order to improve the manufacturing process, it has been found that from when an insulating film is applied and until it is completely cured, dents are made due to external impacts. If micro circuits are formed without recovering the dents, short-circuits and open-circuits arise.

Furthermore, even if the board is not broken, it still has dent marks such that the surface is not flattened even with high temperature for complete curing. When a polyethylene terephthalate (PET) film is removed after an insulating material is applied, the surface of the insulating layer is not evenly cured, resulting in delamination deviation. Therefore, epoxy and silica having weak adhesion are imprinted onto the polyethylene terephthalate (PET) film, such that the surface is not sufficiently flattened and thus unetched portions increase when circuits are formed. Further, if the overall curing rate is fast, when an insulating film is applied, the insulating layers are cured before the insulating film fills between circuit patterns, such that voids are made between the insulating layers. Accordingly, insulation property is deteriorated and defects are increased.

### PRIOR ART DOCUMENT

### Patent Document

(Patent Document 1) Korean Patent Laid-Open Publication No. 2004-0042315

### SUMMARY OF THE INVENTION

The present invention has been made in an effort to provide a laminate for a printed circuit board which, on one hand, is protected from external impacts by way of adjusting the curing rate of insulating layers when a printed circuit board (PCB) is manufactured and, on the other hand, minimizes factors causing defects when micro circuits are formed, and a printed circuit board using the same.

According to a first preferred embodiment of the present invention, there is provided a laminate for a printed circuit board including: a first insulating film; and a second insulating film formed on the first insulating film, wherein a content of a reaction accelerator in the first insulating film is different from that of the second insulating film.

The amount of the reaction accelerator contained in the first insulating film may be smaller than that of the second insulating film.

The laminate may further include: a protective film formed on one surface of the first insulating film; and a support film formed on one surface of the second insulating film.

The reaction accelerator may be imidazole.

According to a second preferred embodiment of the present invention, there is provided a printed circuit board including: a plurality of circuit layers; and insulating layers interposed between the circuit layers, wherein at least one of the insulating layers includes a first insulating film and a second insulating film formed on the first insulating film, wherein the content of a reaction accelerator in the first insulating film is different from that of the second insulating film.

The amount of the reaction accelerator contained in the first insulating film may be smaller than that of the second insulating film, and the first insulating film may be located at the inner side of the board.

The reaction accelerator may be imidazole.

The printed circuit board may further include a via electrically connecting between the circuit layers.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of a laminate for a printed circuit board according to a preferred embodiment of the present invention; and

FIG. 2 is a cross-sectional view of a printed circuit board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Laminate for Printed Circuit Board

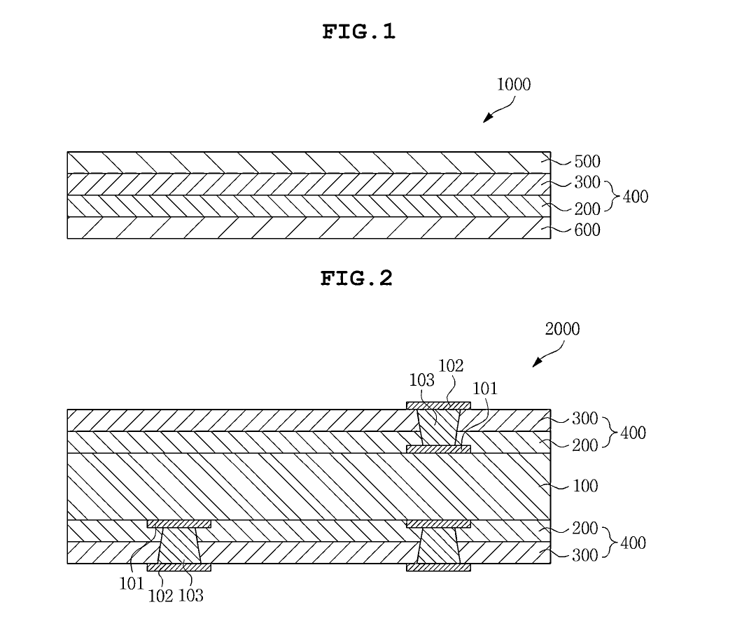

FIG. 1 is a cross-sectional view showing a structure of a laminate for a printed circuit board according to a preferred embodiment of the present invention.

As shown in FIG. 1, the laminate 1000 includes a first insulating film 200 and a second insulating film 300 formed on the first insulating film 200, wherein the content of a reaction accelerator in the first insulating film 200 is different from that of the second insulating film 300.

In addition, the laminate 1000 further includes a protective film 600 formed on one surface of the first insulating film 200 and a support film 500 formed on one surface of the second insulating film 300.

The insulating films 200 and 300 may be made of a resin. The resin may include, but is not limited to, a thermo-setting resin such as an epoxy resin, a thermo-plastic resin such as a polyimide resin, or a resin having a reinforcement material such as a glass fiber or an inorganic filler impregnated in the thermo-setting resin and the thermo-plastic resin, prepreg, for example. In addition, a thermo-setting resin and/or a photo-curable resin may be used, for example.

The protective film 600 may be, but is not limited to, a biaxially oriented poly propylene (BOPP) film.

The support film 500 may be, but is not limited to, a polyethylene terephthalate (PET) film.

Here, the curing rate may be adjusted by varying the content of the reaction accelerator in the first and second insulating films 200 and 300. Other components except the reaction accelerator may be the same.

In an embodiment, the first insulating film 200 may have a lower content of the reaction accelerator than the second insulating film 300.

By doing so, the first insulating film 200 located at inner side of a board 2000 has low viscosity due to the slow curing rate, and thus an insulating material may flow better. Accordingly, the insulating material may evenly fill between micro circuits 101 and 102 formed on the board 2000, leaving no empty space.

In addition, the second insulating film 300 having a lower content of the reaction accelerator may be located at the outer side, so that the surface may be quickly cured as flattening progresses.

Here, the first and second insulating films 200 and 300 may be temporarily attached to each other by a vacuum sucking process, for example. Thereafter, the protective film 600 is removed, such that it is ready to be stacked on a board to be described below.

Here, it is possible to form the laminate with the support film 500 attached on the outer surface of the second insulating film 300 of an insulating layer 400, such that delamination deviation may be reduced when the support film 500 is removed after curing.

Further, the reaction accelerator may be, but is not limited to, imidazole.

Printed Circuit Board

FIG. 2 is a cross-sectional view of a printed circuit board according to a preferred embodiment of the present invention.

As shown in FIG. 2, the printed circuit board 2000 includes a plurality of circuit layers 101 and 102, and a plurality of insulating layers 100 and 400 interposed between the circuit layers 101 and 102. At least one of the insulating layers 100 and 400 includes a first insulating film 200 and a second insulating film 300 formed on the first insulating film 200, wherein the content of a reaction accelerator in the first insulating film 200 is different from that of the second insulating film 300.

In addition, vias 103 may be provided for electrically connecting between the circuit layers.

The material of the circuit layers 101 and 102 is not specifically limited and any material may be used as long as it is applicable to a conductive metal for a circuit, and is typically copper in the case of a printed circuit board.

The insulating layers 100 and 400 may be resin insulating layers. The resin insulating layers may include, but is not limited to, a thermo-setting resin such as an epoxy resin, a thermo-plastic resin such as a polyimide resin, or a resin having a reinforcement material such as a glass fiber or an inorganic filler impregnated in the thermo-setting resin and the thermo-plastic resin, prepreg, for example. In addition, a thermo-setting resin and/or a photo-curable resin may be used, for example.

The first insulating films 200 may be disposed at the inner side of the board 2000.

Here, the curing rate may be adjusted by varying the content of the reaction accelerator in the first and second insulating films 200 and 300. Other components than the reaction accelerator may be the same.

In an embodiment, the first insulating films 200 may have a lower content of the reaction accelerator than the second insulating films 300.

By doing so, the first insulating films 200 located at inner side of the board 2000 have low viscosity due to the slow curing rate, and thus an insulating material may flow better. Accordingly, the insulating material may evenly fill between micro circuits 101 and 102 formed on the board 2000, leaving no empty space.

In addition, the second insulating film 300 having a lower content of the reaction accelerator may be located at the outer side, so that the surface may be quickly cured as flattening progresses.

Here, the reaction accelerator may be, but is not limited to, imidazole.

The laminate for a printed circuit board according to the embodiments of the present invention may minimize defects due to foreign matters and dents caused by external impacts by way of increasing the curing rate on the surface portions.

Further, since the curing rate at the inner side of the laminate is slower than that of the surface portions, an insulating material may fill between micro circuits on a board, thereby reducing voids.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A laminate for a printed circuit board, comprising:
a first insulating film; and
a second insulating film formed on the first insulating film,
wherein a content of a reaction accelerator in the first insulating film is different from that of the second insulating film.

2. The laminate as set forth in claim 1, wherein the amount of the reaction accelerator contained in the first insulating film is smaller than that of the second insulating film

3. The laminate as set forth in claim 2, further comprising: a protective film formed on one surface of the first insulating film; and a support film formed on one surface of the second insulating film.

4. The laminate as set forth in claim 1, wherein the reaction accelerator is imidazole

5. A printed circuit board comprising:
a plurality of circuit layers; and
insulating layers interposed between the circuit layers,
wherein at least one of the insulating layers includes a first insulating film and a second insulating film formed on the first insulating film, wherein the content of a reaction accelerator in the first insulating film is different from that of the second insulating film.

6. The printed circuit board as set forth in claim 5, wherein the amount of the reaction accelerator contained in the first insulating film is smaller than that of the second insulating film, and the first insulating film is located at the inner side of the board.

7. The printed circuit board as set forth in claim 5, wherein the reaction accelerator is imidazole.

8. The printed circuit board as set forth in claim 5, further comprising a via electrically connecting the circuit layers to one another.
